(19) United States
(12) Patent Application Publication
(10) Pub. No.: US 2022/0320074 A1
(43) Pub. Date: Oct. 6, 2022

(54) ELECTROSTATIC DISCHARGE PROTECTION CIRCUIT AND SEMICONDUCTOR DEVICE

(71) Applicant: CHANGXIN MEMORY TECHNOLOGIES, INC., Hefei City (CN)

(72) Inventor: Qian XU, Hefei (CN)

(21) Appl. No.: 17/844,235

(22) Filed: Jun. 20, 2022

Related U.S. Application Data
(63) Continuation of application No. PCT/CN2021/112929, filed on Aug. 17, 2021.

(30) Foreign Application Priority Data
Mar. 10, 2021 (CN) 202110259393.8

(51) Int. Cl. H01L 27/02

(52) U.S. Cl. CPC H01L 27/0266; H01L 27/0296

(57) ABSTRACT

An ESD protection circuit includes: an ESD transistor having a control terminal, a first terminal, a second terminal, and a substrate terminal, the first terminal being electrically connected to a first pad, the second terminal being electrically connected to a second pad; a first transistor having a control terminal, a first terminal, and a second terminal, the control terminal being electrically connected to the second pad, the first terminal being electrically connected to the first pad, the second terminal being electrically connected to the control terminal and the substrate terminal of the ESD transistor; and a second transistor having a control terminal, a first terminal, and a second terminal, the control terminal being electrically connected to the first pad, the first terminal being electrically connected to the control terminal and the substrate terminal of the ESD transistor, the second terminal being electrically connected to the second pad.

### CROSS-REFERENCE TO RELATED APPLICATIONS

This is a continuation application of International Patent Application No. PCT/CN2021/112929, filed on Aug. 17, 2021, which claims priority to Chinese patent application No. 202110259393.8, entitled “ELECTROSTATIC DISCHARGE PROTECTION CIRCUIT AND SEMICONDUCTOR DEVICE” and filed on Mar. 10, 2021. The disclosures of International Patent Application No. PCT/CN2021/112929 and Chinese patent application No. 202110259393.8 are hereby incorporated by reference in their entireties.

### BACKGROUND

With the vigorous development of integrated circuit manufacturing technologies, costs of integrated circuit products decrease rapidly, and the integrated circuit products become increasing diverse and popular. As a level of integration increases, semiconductor devices in integrated circuits become increasingly small, a junction depth becomes increasingly shallow, and a thickness of a gate oxide layer is increasingly thin. All these accelerate the requirement for ESD protection in circuit design.

### SUMMARY

The disclosure relates to, but is not limited to, an Electrostatic Discharge (ESD) protection circuit and a semiconductor device.

An embodiment of the disclosure provides an ESD protection circuit electrically connected to a first pad and a second pad. The ESD protection circuit includes: an ESD transistor configured to discharge static electricity and having a control terminal, a first terminal, a second terminal, and a substrate terminal, the first terminal being electrically connected to the first pad, the second terminal being electrically connected to the second pad; a first transistor having a control terminal, a first terminal, and a second terminal, the control terminal being electrically connected to the second pad, the first terminal being electrically connected to the first pad, the second terminal being electrically connected to the control terminal and the substrate terminal of the ESD transistor; and a second transistor having a control terminal, a first terminal, and a second terminal, the control terminal being electrically connected to the first pad, the first terminal being electrically connected to the control terminal and the substrate terminal of the ESD transistor, the second terminal being electrically connected to the second pad.

An embodiment of the disclosure further provides a semiconductor device, including at least two pads. An ESD protection circuit is disposed between any two pads and electrically connected to the two pads. The ESD protection circuit includes: an ESD transistor, configured to discharge static electricity and having a control terminal, a first terminal, a second terminal, and a substrate terminal, the first terminal being electrically connected to a first pad of the two pads, the second terminal being electrically connected to a second pad of the two pads; a first transistor, having a control terminal, a first terminal, and a second terminal, the control terminal being electrically connected to the second pad, the first terminal being electrically connected to the first pad, the second terminal being electrically connected to the control terminal and the substrate terminal of the ESD transistor; and a second transistor, having a control terminal, a first terminal, and a second terminal, the control terminal being electrically connected to the first pad, the first terminal being electrically connected to the control terminal and the substrate terminal of the ESD transistor, the second terminal being electrically connected to the second pad.

### BRIEF DESCRIPTION OF THE DRAWINGS

To describe the technical solutions in the embodiments of the disclosure more clearly, the following briefly introduces the accompanying drawings required for the embodiments of the disclosure. It is apparent that the accompanying drawings in the following description show merely some embodiments of the disclosure, and a person of ordinary skill in the art may still derive other drawings from these accompanying drawings without creative efforts.

FIG. 1A is a schematic diagram of a circuit structure in which an ESD protection circuit is not disposed according to a first embodiment of the disclosure;

FIG. 1B is a schematic diagram of a circuit structure in which an ESD protection circuit is disposed according to a second embodiment of the disclosure;

FIG. 2 is a schematic diagram of an application of an ESD protection circuit according to a third embodiment of the disclosure;

FIG. 3 is a schematic diagram of an application of an ESD protection circuit according to a fourth embodiment of the disclosure;

FIG. 4 is a schematic diagram of an application of an ESD protection circuit according to a fifth embodiment of the disclosure;

FIG. 5 is a schematic diagram of an application of an ESD protection circuit according to a sixth embodiment of the disclosure;

FIG. 6 is a schematic diagram of a semiconductor device according to an eighth embodiment of the disclosure;

FIG. 7 is a schematic top view of a semiconductor structure forming an ESD transistor of a semiconductor device according to a ninth embodiment of the disclosure;

FIG. 8 is a schematic top view of a semiconductor structure forming an ESD transistor of a semiconductor device according to a tenth embodiment of the disclosure;

FIG. 9 is a schematic top view of a semiconductor structure forming an ESD transistor of a semiconductor device according to an eleventh embodiment of the disclosure; and

FIG. 10 is a schematic principle diagram of a cross-section of the structure shown in FIG. 8.

### DETAILED DESCRIPTION

It should be understood that the following disclosure provides many different embodiments or examples for implementing different features of the disclosure. Specific embodiments or examples of components and layouts are described below to simplify the disclosure. These are only examples and are not intended to limit the disclosure. For example, dimensions of elements are not limited to the ranges or values in the disclosure, and may depend on expected characteristics of process conditions and/or devices. In addition, in the following description, forming a first part above or on a second part may include embodiments in which the first part and the second part are formed in direct contact, and may also include embodiments in which an additional part may be formed between the first part and the second part and therefore the first part and the second part may be not in direct contact. For simplicity and clarity, the parts may be arbitrarily drawn in different proportions.

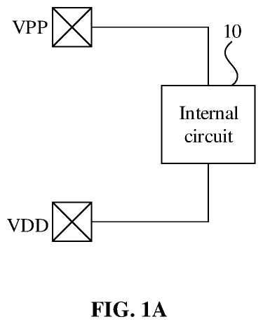

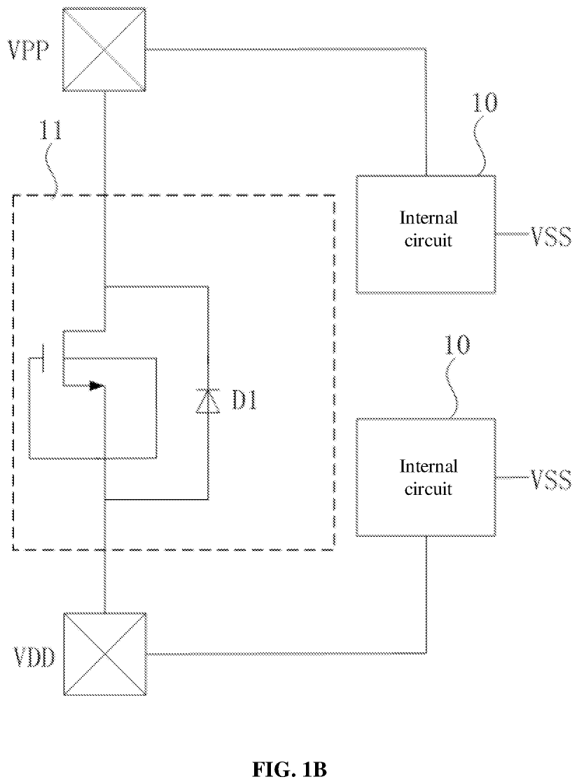

There are a plurality of pads in an integrated circuit. For example, FIG. 1A is a schematic diagram of a circuit structure according to a first embodiment of the disclosure. Referring to FIG. 1A, a circuit has two pads, that is, a first pad VPP and a second pad VDD. The first pad VPP and the second pad VDD are separately connected to an internal circuit 10. When static electricity occurs on one of the pads (for example, the first pad VPP), electrostatic charges may flow through the internal circuit 10 and are discharged through the internal circuit 10 (a current direction is shown by an arrow in the figure), and as a result the internal circuit 10 may be damaged by the static electricity.

To prevent the internal circuit from being damaged by the static electricity, a clamp circuit including a clamp transistor is used as a protection solution for an ESD protection circuit. FIG. 1B is a schematic diagram of a circuit structure in which an ESD protection circuit is disposed according to a second embodiment of the disclosure. An ESD protection circuit 11 is disposed between the first pad VPP and the second pad VDD. The internal circuit 10 is electrically connected to the first pad VPP and the second pad VDD. The ESD protection circuit 11 is also electrically connected to the first pad VPP and the second pad VDD. That is, the ESD protection circuit 11 is connected in parallel to the internal circuit 10. When static electricity occurs on one of the pads (for example, the first pad VPP), the static electricity may be discharged through the ESD protection circuit 11 and does not flow through the internal circuit 10, thereby protecting the internal circuit 10. As such, the static electricity is prevented from entering the internal circuit 10 of the integrated circuit to avoid burning out elements in the internal circuit 10 and at the same time ensure a stable voltage in the internal circuit 10.

Although the ESD protection circuit 11 can discharge the static electricity, when the integrated circuit operates, the first pad VPP and the second pad VDD may be powered on nonsimultaneously. In this case, a parasitic diode of the ESD protection circuit 11 is turned on, such that the function of the ESD protection circuit 11 is affected.

Specifically, referring to FIG. 1B, the ESD protection circuit 11 includes an N-type metal-oxide-semiconductor (NMOS) transistor. A gate, a source, and a substrate of the NMOS transistor are short circuited, and are connected to the second pad VDD. A drain of the NMOS transistor is connected to the first pad VPP.

There is a parasitic diode D1 in the ESD protection circuit 11. When the integrated circuit operates, the first pad VPP and the second pad VDD may be powered on nonsimultaneously. As a result, the parasitic diode D1 of the ESD protection circuit is turned on. Electric charges are discharged through the parasitic diode D1, thereby affecting the function of the internal circuit 10. For example, when the second pad VDD is powered on first and the first pad VPP is still not powered on, the parasitic diode D1 of the ESD protection circuit 11 is turned on. A current flows through the parasitic diode D1, such that the function of the internal circuit is affected.

In view of the foregoing reasons, the disclosure provides an ESD protection circuit, which may prevent pads from being connected caused by the pads being powered on nonsimultaneously, thereby avoiding affecting the internal circuit.

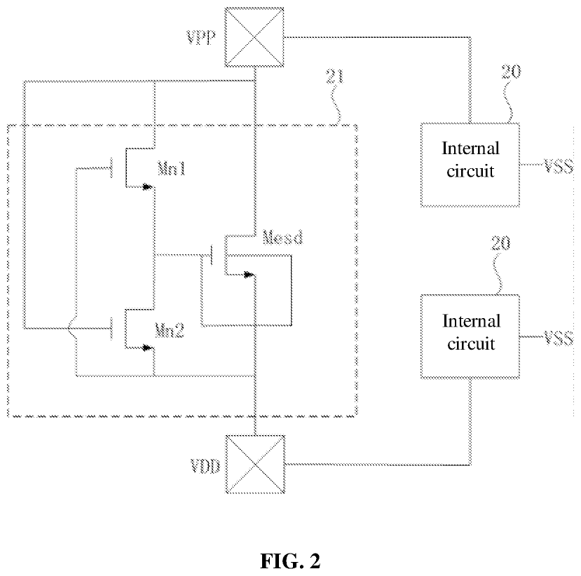

FIG. 2 is a schematic diagram of an application of an ESD protection circuit according to a third embodiment of the disclosure. Referring to FIG. 2, an internal circuit 20 is electrically connected to the first pad VPP and the second pad VDD. An ESD protection circuit 21 is also electrically connected to the first pad VPP and the second pad VDD. That is, the ESD protection circuit 21 is connected in parallel to the internal circuit 20. When static electricity occurs on one of the pads (for example, the second pad VDD), the static electricity is discharged through the ESD protection circuit 21 and does not flow through the internal circuit 20, thereby protecting the internal circuit 20 and preventing the internal circuit 20 from being damaged by the static electricity.

In this embodiment, the first pad VPP is a first power pad, and the second pad VDD is a second power pad. In another embodiment of the disclosure, the first pad may be a first grounding pad, and the second pad may be a second grounding pad.

The ESD protection circuit 21 in the disclosure includes an ESD transistor Mesd, a first transistor Mn1, and a second transistor Mn2.

The ESD transistor Mesd is used for discharging static electricity, and has a control terminal, a first terminal, a second terminal, and a substrate terminal. The first terminal is electrically connected to the first pad VPP. The second terminal is electrically connected to the second pad VDD. In this embodiment, the ESD transistor Mesd is an NMOS transistor. The control terminal of the ESD transistor Mesd is a gate terminal of the NMOS transistor. The first terminal of the ESD transistor Mesd is a drain terminal of the NMOS transistor. The second terminal of the ESD transistor Mesd is a source terminal of the NMOS transistor. The substrate terminal of the ESD transistor Mesd is a substrate terminal of the NMOS transistor.

The first transistor Mn1 has a control terminal, a first terminal, and a second terminal. The control terminal is electrically connected to the second pad VDD. The first terminal is electrically connected to the first pad VPP. The second terminal is electrically connected to the control terminal and the substrate terminal of the ESD transistor Mesd. In this embodiment, the first transistor Mn1 is an NMOS transistor. The control terminal of the first transistor Mn1 is a gate terminal of the NMOS transistor, and is electrically connected to the second pad VDD. The first terminal of the first transistor Mn1 is a source terminal of the NMOS transistor, and is electrically connected to the first pad VPP. The second terminal of the first transistor Mn1 is a drain terminal of the NMOS transistor, and is electrically connected to the control terminal and the substrate terminal of the ESD transistor Mesd.

The second transistor Mn2 has a control terminal, a first terminal, and a second terminal. The control terminal is electrically connected to the first pad VPP. The first terminal is electrically connected to the control terminal and the substrate terminal of the ESD transistor Mesd. The second terminal is electrically connected to the second pad VDD. In this embodiment, the second transistor Mn2 is an NMOS transistor. The control terminal of the second transistor Mn2 is a gate terminal of the NMOS transistor, and is electrically connected to the first pad VPP. The first terminal of the second transistor Mn2 is a drain terminal of the NMOS transistor, and is electrically connected to the control terminal and the substrate terminal of the ESD transistor Mesd. The second terminal of the second transistor Mn2 is a source terminal of the NMOS transistor, and is electrically connected to the second pad VDD.

During normal operation of the circuit, when the first pad VPP is powered on first, that is, when a voltage of the first pad VPP is greater than a voltage of the second pad VDD, the second transistor Mn2 is turned on. The control terminal of the ESD transistor Mesd is at a low level, and the substrate terminal of the ESD transistor Mesd is at a low level. A parasitic diode of the ESD transistor Mesd is reversely biased and is turned off. As such, electric charges are prevented from being discharged through the parasitic diode of the ESD transistor Mesd, thereby ensuring the normal operation of the internal circuit 20.

During normal operation of the circuit, when the second pad VDD is powered on first, that is, when the voltage of the first pad VPP is less than the voltage of the second pad VDD, the first transistor Mn1 is turned on. The control terminal of the ESD transistor Mesd is still at a low level, and the substrate terminal of the ESD transistor Mesd is at a low level. The parasitic diode of the ESD transistor Mesd is reversely biased and is turned off. As such, electric charges are prevented from being discharged through the parasitic diode of the ESD transistor Mesd, thereby ensuring the normal operation of the internal circuit 20.

In the disclosure, when the different pads are powered on nonsimultaneously, the ESD protection circuit can prevent electric charges from being discharged through the parasitic diode of the ESD protection circuit, thereby ensuring the normal operation of the internal circuit 20, and also ensuring the normal operation of the ESD protection circuit. The ESD protection circuit in the disclosure does not affect the performance of a semiconductor device, and may realize ESD protection among the different pads, thereby effectively ensuring the reliability of the semiconductor device and improving the competitiveness of the semiconductor device.

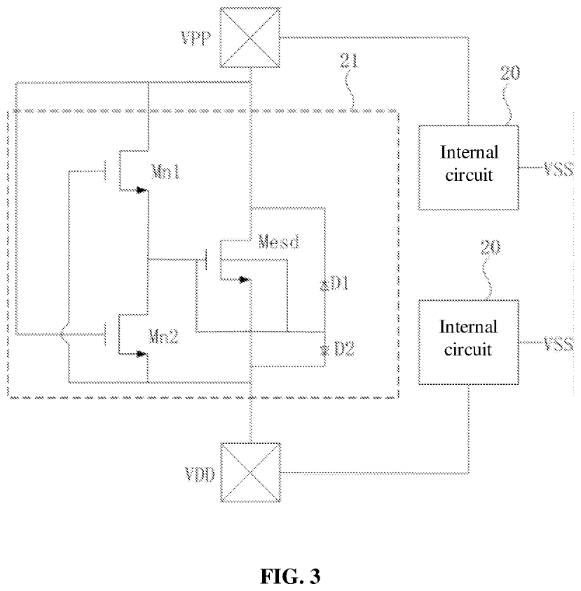

FIG. 3 is a schematic diagram of an application of an ESD protection circuit according to a fourth embodiment of the disclosure. Referring to FIG. 3, in the fourth embodiment of the disclosure, a first parasitic diode D1 is provided between the substrate terminal of the ESD transistor Mesd and the first terminal of the ESD transistor Mesd. An anode of the first parasitic diode D1 is connected to the substrate terminal of the ESD transistor Mesd. A cathode of the first parasitic diode D1 is electrically connected to the first terminal of the ESD transistor Mesd. Further, a second parasitic diode D2 is provided between the substrate terminal of the ESD transistor Mesd and the second terminal of the ESD transistor Mesd. An anode of the second parasitic diode D2 is connected to the substrate terminal of the ESD transistor Mesd. A cathode of the second parasitic diode D2 is electrically connected to the second terminal of the ESD transistor Mesd.

During normal operation of the circuit, when the first pad VPP is powered on first, that is, when the voltage of the first pad VPP is greater than the voltage of the second pad VDD, the second transistor Mn2 is turned on. The control terminal of the ESD transistor Mesd is at a low level, and the substrate terminal of the ESD transistor Mesd is at a low level. The first parasitic diode D1 and the second parasitic diode D2 of the ESD transistor Mesd are reversely biased and are not turned on, to prevent electric charges from being discharged through the first parasitic diode D1, thereby ensuring the normal operation of the internal circuit 20.

During normal operation of the circuit, when the second pad VDD is powered on first, that is, when the voltage of the first pad VPP is less than the voltage of the second pad VDD, the first transistor Mnl is turned on. The control terminal of the ESD transistor Mesd is still at a low level, and the substrate terminal of the ESD transistor Mesd is at a low level. The first parasitic diode D1 and the second parasitic diode D2 of the ESD transistor Mesd are reversely biased and are not turned on, to prevent electric charges from being discharged through the first parasitic diode D1 and the second parasitic diode D2, thereby ensuring the normal operation of the internal circuit 20.

When static electricity needs to be discharged through the ESD transistor Mesd and electrostatic charges occur on the first pad VPP, the first parasitic diode D1 is reversely broken down, the second parasitic diode D2 is turned on, and the electrostatic charges on the first pad VPP are discharged through the second parasitic diode D2. When static electricity needs to be discharged through the ESD transistor Mesd and electrostatic charges occur on the second pad VDD, the second parasitic diode D2 is reversely broken down, the first parasitic diode D1 is turned on, and the electrostatic charges on the second pad VDD are discharged through the first parasitic diode D1, to implement the discharge of the electrostatic charges on the pads.

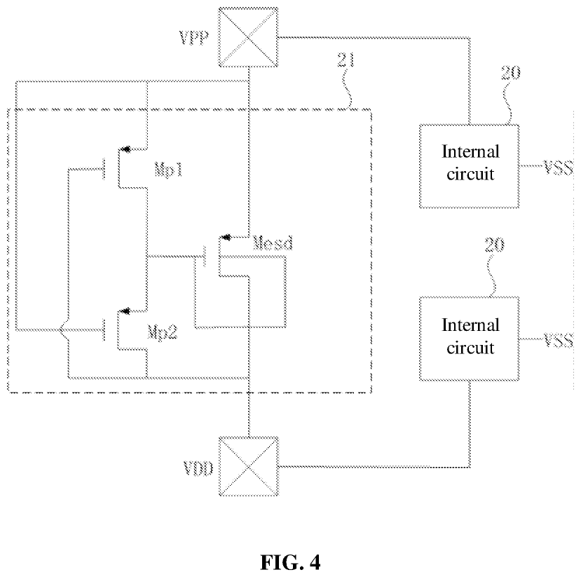

In the embodiment, the first transistor Mn1, the second transistor Mn2, and the ESD transistor Mesd are all NMOS transistors. In another embodiment of the disclosure, the first transistor, the second transistor, and the ESD transistor Mesd are all P-type metal-oxide-semiconductor (PMOS) transistors. Specifically, FIG. 4 is a schematic diagram of an application of an ESD protection circuit according to a fifth embodiment of the disclosure. In the fifth embodiment, a first transistor Mp1, a second transistor Mp2, and the ESD transistor Mesd are all PMOS transistors.

A control terminal of the first transistor Mp1 is a gate terminal of the PMOS transistor, and is electrically connected to the second pad VDD. A first terminal of the first transistor Mp1 is a source terminal of the PMOS transistor, and is electrically connected to the first pad VPP. A second terminal of the first transistor Mp1 is a drain terminal of the PMOS transistor, and is electrically connected to the control terminal and the substrate terminal of the ESD transistor Mesd.

A control terminal of the second transistor Mp2 is a gate terminal of the PMOS transistor, and is electrically connected to the first pad VPP. A first terminal of the second transistor Mp2 is a drain terminal of the PMOS transistor, and is electrically connected to the control terminal and the substrate terminal of the ESD transistor Mesd. A second terminal of the second transistor Mp2 is a source terminal of the PMOS transistor, and is electrically connected to the second pad VDD.

During normal operation of the circuit, when the first pad VPP is powered on first, that is, when the voltage of the second pad VDD is less than the voltage of the first pad VPP, the first transistor Mp1 is turned on. The control terminal of the ESD transistor Mesd is at a low level, and the substrate terminal of the ESD transistor Mesd is at a low level. A parasitic diode of the ESD transistor Mesd is reversely biased and is not turned on, to prevent electric charges from being discharged through the parasitic diode of the ESD transistor Mesd, thereby ensuring the normal operation of the internal circuit 20.

During normal operation of the circuit, when the second pad VDD is powered on first, that is, when the voltage of the first pad VPP is less than the voltage of the second pad VDD, the second transistor Mp2 is turned on. The control terminal of the ESD transistor Mesd is still at a low level, and the substrate terminal of the ESD transistor Mesd is at a low level. A parasitic diode of the ESD transistor Mesd is reversely biased and is not turned on, to prevent electric charges from being discharged through the parasitic diode of the ESD transistor Mesd, thereby ensuring the normal operation of the internal circuit 20.

In the embodiment, when the different pads are powered on nonsimultaneously, the ESD protection circuit can prevent electric charges from being discharged through the parasitic diode of the ESD protection circuit, thereby ensuring the normal operation of the internal circuit 20, and also ensuring the normal operation of the ESD protection circuit. The ESD protection circuit in the disclosure does not affect the performance of a semiconductor device, and may realize ESD protection among the different pads, thereby effectively ensuring the reliability of the semiconductor device and improving the competitiveness of the semiconductor device.

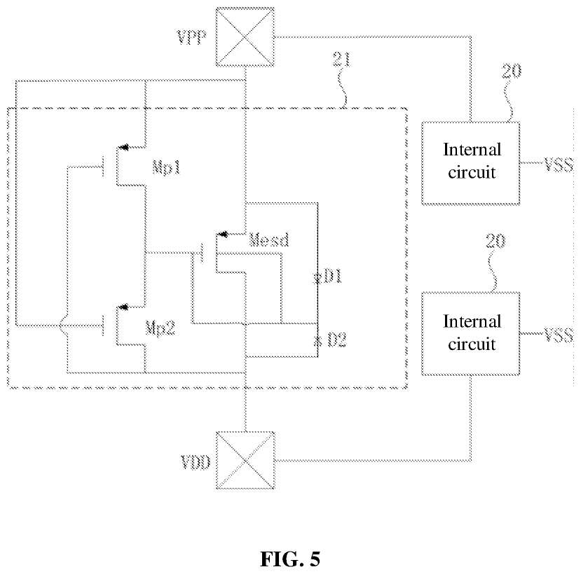

FIG. 5 is a schematic diagram of an application of an ESD protection circuit according to a sixth embodiment of the disclosure. Referring to FIG. 5, in the embodiment of the disclosure, a first parasitic diode D1 is provided between the substrate terminal of the ESD transistor Mesd and the first terminal of the ESD transistor Mesd. The cathode of the first parasitic diode D1 is connected to the substrate terminal of the ESD transistor Mesd. The anode of the first parasitic diode D1 is electrically connected to the first terminal of the ESD transistor Mesd. Further, a second parasitic diode D2 is provided between the substrate terminal of the ESD transistor Mesd and the second terminal of the ESD transistor Mesd. The cathode of the second parasitic diode D2 is connected to the substrate terminal of the ESD transistor Mesd. The anode of the second parasitic diode D2 is electrically connected to the second terminal of the ESD transistor Mesd.

During normal operation of the circuit, when the first pad VPP is powered on first, that is, when the voltage of the second pad VDD is less than the voltage of the first pad VPP, the first transistor Mp1 is turned on. The control terminal of the ESD transistor Mesd is at a low level, and the substrate terminal of the ESD transistor Mesd is at a low level. The first parasitic diode D1 and the second parasitic diode D2 of the ESD transistor Mesd are reversely biased and are not turned on, to prevent electric charges from being discharged through the first parasitic diode D1 and the second parasitic diode D2 of the ESD transistor Mesd, thereby ensuring the normal operation of the internal circuit 20.

During normal operation of the circuit, when the second pad VDD is powered on first, that is, when the voltage of the first pad VPP is less than the voltage of the second pad VDD, the second transistor Mp2 is turned on. The control terminal of the ESD transistor Mesd is still at a low level, and the substrate terminal of the ESD transistor Mesd is at a low level. The first parasitic diode D1 and the second parasitic diode D2 are reversely biased and are not turned on, to prevent electric charges from being discharged through the first parasitic diode D1 or the second parasitic diode D2, and the second transistor Mp2, thereby ensuring the normal operation of the internal circuit 20.

When static electricity needs to be discharged through the ESD transistor Mesd and electrostatic charges occur on the first pad VPP, the second parasitic diode D2 is reversely broken down, the first parasitic diode D1 is turned on, and the electrostatic charges on the first pad VPP are discharged through the first parasitic diode D1. When static electricity needs to be discharged through the ESD transistor Mesd and electrostatic charges occur on the second pad VDD, the first parasitic diode D1 is reversely broken down, the second parasitic diode D2 is turned on, and the electrostatic charges on the second pad VDD are discharged through the second parasitic diode D2, to implement the discharge of the electrostatic charges on the pads.

The disclosure further provides a semiconductor device. The semiconductor device includes at least two pads. The foregoing ESD protection circuit is disposed between any two pads. Continuing to refer to FIG. 2, in a semiconductor device provided in a seventh embodiment of the disclosure, the semiconductor device of the disclosure includes two pads, namely, the first pad VPP and the second pad VDD. The ESD protection circuit 21 is electrically connected to the first pad VPP and the second pad VDD.

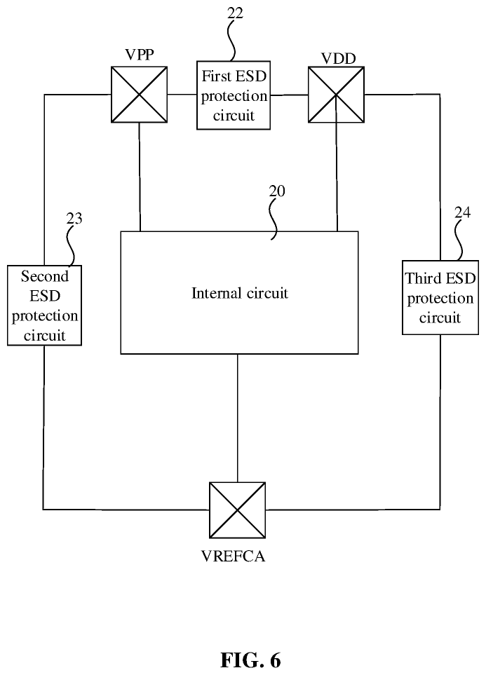

The disclosure further provides an eighth embodiment. In the eighth embodiment, the semiconductor device includes three pads. Specifically, FIG. 6 is a schematic diagram of a semiconductor device according to the eighth embodiment of the disclosure. The semiconductor device includes a first pad VPP, a second pad VDD, and a third pad VREFCA. A first ESD protection circuit 22 is electrically connected to the first pad VPP and the second pad VDD. A second ESD protection circuit 23 is electrically connected to the first pad VPP and the third pad VREFCA. A third ESD protection circuit 24 is electrically connected to the second pad VDD and the third pad VREFCA. The structures of the first ESD protection circuit 22, the second ESD protection circuit 23, and the third ESD protection circuit 24 are the same as the structure of the foregoing ESD protection circuit 21. Details are not described again.

When the first pad VPP, the second pad VDD, and the third pad VREFCA are powered on nonsimultaneously, the first ESD protection circuit 22, the second ESD protection circuit 23, and the third ESD protection circuit 24 can prevent electric charges from being discharged through the parasitic diodes of the ESD protection circuits, thereby ensuring the normal operation of the internal circuit 20, and also ensuring the normal operation of the ESD protection circuits, thereby effectively improving the reliability of the semiconductor device and improving the competitiveness of the semiconductor device.

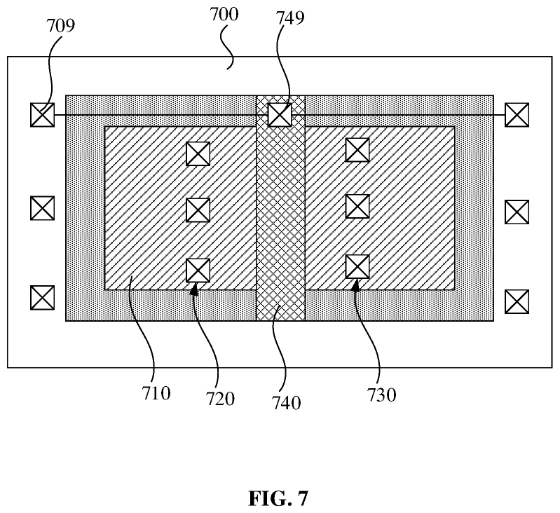

FIG. 7 is a schematic top view of a semiconductor structure forming an ESD transistor of a semiconductor device according to a ninth embodiment of the disclosure. Referring to FIG. 7, a semiconductor structure forming the ESD transistor includes: a semiconductor substrate 700, a well region 710, a source region 720, a drain region 730, and a gate 740.

The semiconductor substrate 700 may be a monocrystalline silicon substrate, a Ge substrate, a SiGe substrate, an SOI, a GOI or the like. According to an actual requirement of a device, an appropriate semiconductor material may be selected for the semiconductor substrate 700. This is not limited herein. A plurality of connecting pads 709 are disposed in the semiconductor substrate 700.

The well region 710 is disposed in the semiconductor substrate 700. In this embodiment, because the ESD transistor is an NMOS transistor, the well region is a P-type region.

The source region 720 and the drain region 730 are alternately arranged at an interval in the well region 710. In this embodiment, because the well region 710 is a P-type region, the source region 720 and the drain region 730 are N-type regions.

The gate 740 is disposed on the semiconductor substrate 700, and is located between the source region 720 and the drain region 730. The gate 740 is electrically connected to the semiconductor substrate 700. Specifically, the gate 740 is electrically connected to the connecting pads 709 of the semiconductor substrate 700 through a connecting pad 749, to implement an electrical connection between the gate 740 and the semiconductor substrate 700. That is, the control terminal of the ESD transistor is electrically connected with the substrate terminal of the ESD transistor.

In this embodiment, the semiconductor structure includes one source region 720, one drain region 730, and one gate 740. In another embodiment of the disclosure, the semiconductor structure may include a plurality of source regions 720, a plurality of drain regions 730, and a plurality of gates 740.

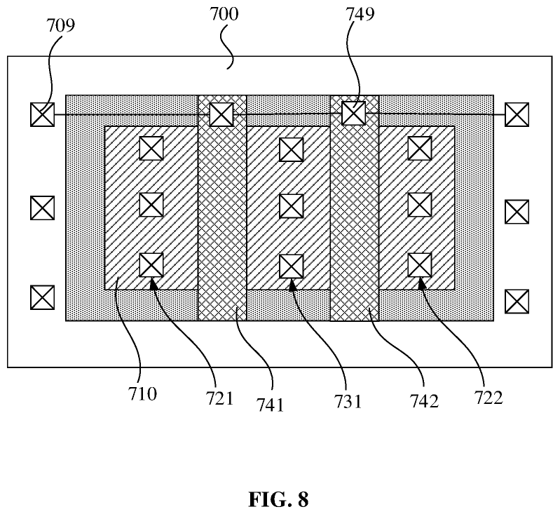

FIG. 8 is a schematic top view of a semiconductor structure forming an ESD transistor of a semiconductor device according to a tenth embodiment of the disclosure. Referring to FIG. 8, in this embodiment, the semiconductor structure includes a first source region 721, a second source region 722, a first drain region 731, a first gate 741, and a second gate 742. The first drain region 731 is located between the first source region 721 and the second source region 722. The first gate 741 is located between the first source region 721 and the first drain region 731. The second gate 742 is located between the first drain region 731 and the second source region 722. In the embodiment, the first drain region 731 is used as a common drain region. The connecting pads 749 of the first gate 741 and the second gate 742 are electrically connected to the connecting pads 709 of the semiconductor substrate 700, so that the first gate 741 and the second gate 742 are electrically connected to the semiconductor substrate 700. That is, the control terminal of the ESD transistor is electrically connected with the substrate terminal of the ESD transistor.

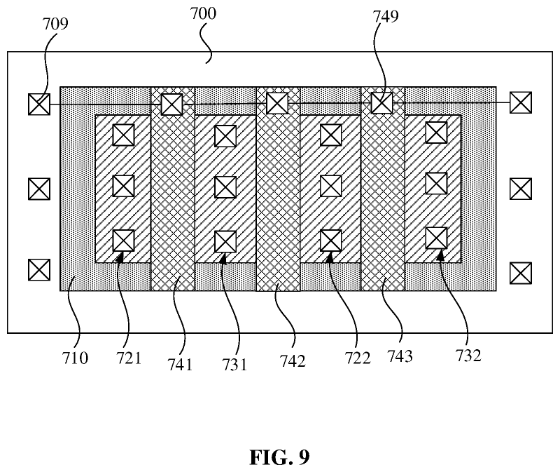

FIG. 9 is a schematic top view of a semiconductor structure forming an ESD transistor of a semiconductor device according to an eleventh embodiment of the disclosure. Referring to FIG. 9, in this embodiment, the semiconductor structure includes a plurality of source regions, a plurality of drain regions, and a plurality of gates. The plurality of source regions and the plurality of drain regions are alternately arranged at intervals, and a gate is disposed between a source region and a drain region that are adjacent.

Specifically, in this embodiment, the semiconductor structure includes a first source region 721, a second source region 722, a first drain region 731, a second drain region 732, a first gate 741, a second gate 742, and a third gate 743. The first source region 721, the first drain region 731, the second source region 722, and the second drain region 732 are alternately arranged at intervals. The first gate is disposed between the first source region 721 and the first drain region 731. The second gate 742 is disposed between the first drain region 731 and the second source region 722. The third gate 743 is disposed between the second source region 722 and the second drain region 732. It may be understood that in another embodiment of the disclosure, a plurality of source regions, a plurality of drain regions, and a plurality of gates may be disposed according to the foregoing arrangement rule. Details are not described herein again.

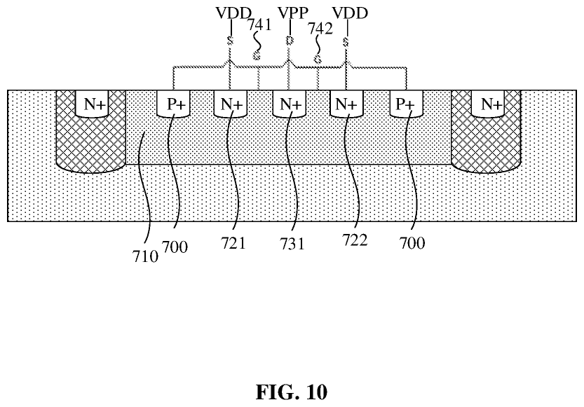

The structure shown in FIG. 8 is used as an example below to describe the principle that the ESD protection circuit in the disclosure can prevent electric charges from being discharged through the parasitic diode of the ESD protection circuit. FIG. 10 is a schematic principle diagram of a cross-section of the structure shown in FIG. 8. Referring to FIG. 8 and FIG. 10, the first gate 741, the second gate 742, and the semiconductor substrate 700 of the ESD transistor are short circuited. That is, the control terminal and the substrate terminal of the ESD transistor Mesd shown in FIG. 2 are short circuited, and the control terminal of the ESD transistor Mesd is at the same potential as the substrate terminal of the ESD transistor Mesd.

The first parasitic diode is provided between the semiconductor substrate 700 and the first drain region 731 of the ESD transistor. The second parasitic diode is provided between the semiconductor substrate 700 and the first source region 721 and the second source region 722 of the ESD transistor. When a pad (for example, the second pad VDD shown in FIG. 2) electrically connected to the ESD protection circuit is powered on first, because the substrate terminal of the ESD transistor is at a low level, the first parasitic diode and the second parasitic diode are reversely biased and are not turned on. The ESD protection circuit can prevent electric charges from being discharged through the first parasitic diode and the second parasitic diode, thereby ensuring normal operation of an internal circuit and improving the reliability and competitiveness of the semiconductor device.

The foregoing descriptions are some implementations of the disclosure. It should be noted that for a person of ordinary skill in the art, several improvements and modifications may further be made without departing from the principle of the disclosure. These improvements and modifications should also be deemed as falling within the scope of protection of the disclosure.

1. An Electrostatic Discharge (ESD) protection circuit, electrically connected to a first pad and a second pad, the ESD protection circuit comprising:
an ESD transistor, configured to discharge static electricity and having a control terminal, a first terminal, a second terminal, and a substrate terminal, the first terminal being electrically connected to the first pad, the second terminal being electrically connected to the second pad;
a first transistor, having a control terminal, a first terminal, and a second terminal, the control terminal being electrically connected to the second pad, the first terminal being electrically connected to the first pad, the second terminal being electrically connected to the control terminal and the substrate terminal of the ESD transistor; and
a second transistor, having a control terminal, a first terminal, and a second terminal, the control terminal being electrically connected to the first pad, the first terminal being electrically connected to the control terminal and the substrate terminal of the ESD transistor, the second terminal being electrically connected to the second pad.

2. The ESD protection circuit of claim 1, wherein the first transistor and the second transistor are both N-type metal-oxide-semiconductor (NMOS) transistors.

3. The ESD protection circuit of claim 2, wherein the ESD transistor is an NMOS transistor.

4. The ESD protection circuit of claim 2, wherein the first pad is a first power pad, and the second pad is a second power pad.

5. The ESD protection circuit of claim 1, wherein the first transistor and the second transistor are both P-type metal-oxide-semiconductor (PMOS) transistors.

6. The ESD protection circuit of claim 5, wherein the ESD transistor is a PMOS transistor.

7. The ESD protection circuit of claim 5, wherein the first pad is a first grounding pad, and the second pad is a second grounding pad.

8. The ESD protection circuit of claim 1, wherein a first parasitic diode is provided between the substrate terminal of the ESD transistor and the first terminal of the ESD transistor, a second parasitic diode is provided between the substrate terminal of the ESD transistor and the second terminal of the ESD transistor, and when a voltage of the first pad is greater than a voltage of the second pad or when a voltage of the first pad is less than a voltage of the second pad, neither of the first parasitic diode and the second parasitic diode is turned on.

9. The ESD protection circuit of claim 8, wherein when static electricity occurs, the first parasitic diode is reversely broken down, and the second parasitic diode is turned on, to discharge the static electricity; or, when static electricity occurs, the first parasitic diode is turned on, and the second parasitic diode is reversely broken down, to discharge the static electricity.

10. A semiconductor device, comprising at least two pads, wherein an Electrostatic Discharge (ESD) protection circuit is disposed between any two pads and electrically connected to the two pads, the ESD protection circuit comprises:
an ESD transistor, configured to discharge static electricity and having a control terminal, a first terminal, a second terminal, and a substrate terminal, the first terminal being electrically connected to a first pad of the two pads, the second terminal being electrically connected to a second pad of the two pads;
a first transistor, having a control terminal, a first terminal, and a second terminal, the control terminal being electrically connected to the second pad, the first terminal being electrically connected to the first pad, the second terminal being electrically connected to the control terminal and the substrate terminal of the ESD transistor; and
a second transistor, having a control terminal, a first terminal, and a second terminal, the control terminal being electrically connected to the first pad, the first terminal being electrically connected to the control terminal and the substrate terminal of the ESD transistor, the second terminal being electrically connected to the second pad.

11. The semiconductor device of claim 10, wherein a semiconductor structure forming the ESD transistor further comprises:
a semiconductor substrate;
a well region disposed in the semiconductor substrate;
a source region and a drain region alternately arranged at an interval and disposed in the well region; and
a gate disposed on the semiconductor substrate and located between the source region and the drain region, the gate being electrically connected to the semiconductor substrate.

12. The semiconductor device of claim 11, wherein the well region is a P-type region, and the source region and the drain region are N-type regions.

13. The semiconductor device of claim 11, wherein the semiconductor structure further comprises a first source region, a second source region, a first drain region, a first gate, and a second gate, the first drain region is located between the first source region and the second source region, the first gate is located between the first source region and the first drain region, and the second gate is located between the first drain region and the second source region.

14. The semiconductor device of claim 11, wherein the semiconductor structure further comprises a plurality of source regions, a plurality of drain regions, and a plurality of gates, the plurality of source regions and the plurality of drain regions are alternately arranged at intervals, and a gate is disposed between a source region and a drain region that are adjacent.

15. The semiconductor device of claim 11, wherein the gate is electrically connected to the second terminal of the first transistor and the first terminal of the second transistor.

16. The semiconductor device of claim 10, wherein the first transistor and the second transistor are both N-type metal-oxide-semiconductor (NMOS) transistors.

17. The semiconductor device of claim 16, wherein the ESD transistor is an NMOS transistor.

18. The semiconductor device of claim 16, wherein the first pad is a first power pad, and the second pad is a second power pad.

19. The semiconductor device of claim 10, wherein the first transistor and the second transistor are both P-type metal-oxide-semiconductor (PMOS) transistors.

20. The semiconductor device of claim 19, wherein the ESD transistor is a PMOS transistor.
